(19) United States
(12) Patent Application Publication
(10) Pub. No.: US 2016/0177015 A1
(43) Pub. Date: Jun. 23, 2016

(54) Dispersion for Simple Use in The Production of Encapsulation Films

(71) Applicants: Daniel ULBRICHT, Darmstadt (DE); Marcel HEIN, Niedernberg (DE); Frank Kleff, Bruchkoebel-Oberissigheim (DE); Stephanie SCHAUHOFF, Langen (DE); Juergen OHLEMACHER, Bad Vilbel (DE)

(72) Inventors: Daniel ULBRICHT, Darmstadt (DE); Marcel HEIN, Niedernberg (DE); Frank Kleff, Bruchkoebel-Oberissigheim (DE); Stephanie SCHAUHOFF, Langen (DE); Juergen OHLEMACHER, Bad Vilbel (DE)

(73) Assignee: Evonik Degussa GmbH, Essen (DE)

(21) Appl. No.: 14/974,814

(22) Filed: Dec. 18, 2015

(30) Foreign Application Priority Data
Dec. 19, 2014 (EP) 14199296

(51) Int. Cl. C08F 255/02; H01L 31/0203; C08J 5/18; C08K 5/14; C08K 5/5425

(52) U.S. Cl. CPC C08F 255/026; C08K 5/14; C08K 5/5425; C08J 5/18; H01L 31/0203; C08J 2351/06

(57) ABSTRACT

A dispersion (D) contains (i) at least one polyolefin copolymer (I) as continuous phase; and (ii) at least one (meth)acrylamide compound dispersed in the polyolefin copolymer (I). The dispersion (D) is used for the production of a film for encapsulation of an electronic device, especially a solar cell.

### BACKGROUND OF THE INVENTION

1. Field of the Invention

The present invention relates to a dispersion (D) comprising (i) at least one polyolefin copolymer (I) as continuous phase; and (ii) at least one (meth)acrylamide compound dispersed in the polyolefin copolymer (I). The present invention additionally relates to the use of the dispersion (D) for production of a film for encapsulation of an electronic device, especially a solar cell. The invention further relates to a process for producing the dispersion (D). Finally, the invention also relates to the dispersion (D) obtained with the aid of this process.

2. Discussion of the Background

Photovoltaic modules (photovoltaic=“PV”) typically consist of a layer of symmetrically arranged silicon cells welded into two layers of a protective film. This protective film is itself stabilized in turn by a “backsheet” on its reverse side and a “frontsheet” on its front side. The backsheet and frontsheet may either be suitable polymer films or consist of glass. The function of the encapsulation material is essentially to protect the PV module from weathering effects and mechanical stress, and for that reason the mechanical stability of the particular encapsulation material is an important property. In addition, good encapsulation materials have a rapid curing rate, high gel content, high transmission, low tendency to temperature- and heat-induced discolouration and high adhesion (i.e. a low tendency to UV-induced delamination).

The encapsulation materials described for this purpose in the related art (for example WO 2008/036708 A2) are typically based on materials such as silicone resins, polyvinyl butyral resins, ionomers, polyolefin films or ethylene-vinyl acetate copolymers (“EVA”).

Processes for production of such encapsulation films are familiar to those skilled in the art. In these processes, the crosslinkers are mixed homogeneously together with a polyolefin copolymer (and possibly further additives) in an extruder, for example, and then extruded to give a film. EVA encapsulation films are described, for example, by EP 1 164 167 A1. The process described therein is also applicable to films made from other materials, for example those mentioned above.

The encapsulation of the silicon cells is typically effected in a vacuum lamination oven (EP 2 457 728 A1). For this purpose, the layer structure of the PV module is prepared and first heated up gradually in a lamination oven (consisting of two chambers separated by a membrane). This softens the polyolefin copolymer (for example EVA). At the same time, the oven is evacuated in order to remove the air between the layers. This step is the most critical and takes between 4 and 6 minutes. Subsequently, the vacuum is broken by means of the second chamber, and the layers of the module are welded to one another by means of application of a pressure. At the same time, heating is continued up to the crosslinking temperature, in which case the crosslinking of the film takes place in this last step.

EVA in particular is used as standard in the production of encapsulation films for solar modules. However, it also has a lower specific electrical resistance ρ than the latter. This makes the use of EVA films as encapsulation material less attractive, since it is specifically encapsulation materials having high specific electrical resistance ρ that are desired.

This is because, in the case of PV modules, what is called the “PID” effect (PID=potential-induced degradation) is currently a major quality problem. The term “PID” is understood to mean a voltage-related performance degradation caused by what are called “leakage currents” within the PV module.

Causes of the damaging leakage currents are, as well as the setup of the solar cell, the voltage level of the individual PV modules with respect to the earth potential—in the case of most unearthed PV systems, the PV modules are subjected to a positive or negative voltage. PID usually occurs at a negative voltage relative to earth potential and is accelerated by high system voltages, high temperatures and high air humidity. As a result, sodium ions migrate out of the cover glass of the PV module to the interface of the solar cell and cause damage (“shunts”) there, which lead to performance losses or even to the total loss of the PV module.

The risk of occurrence of a PID effect can be distinctly reduced by increasing the specific electrical resistance ρ of the encapsulation films.

The specific electrical resistance ρ or else volume resistivity (also abbreviated hereinafter to “VR”) is a temperature-dependent material constant. It is utilized to calculate the electrical resistivity of a homogeneous electrical conductor. Specific electrical resistance is determined in accordance with the invention by means of ASTM-D257.

The higher the specific electrical resistance ρ of a material, the less photovoltaic modules are prone to the PID effect. A significant positive effect in increasing the specific electrical resistance ρ of encapsulation films is therefore the increase in the lifetime and efficiency of PV modules.

The related art discusses the problem of the PID effect in connection with encapsulation films for PV modules in CN 103525321 A. This document describes an EVA-based film for encapsulation of solar cells, containing triallyl isocyanurate (“TAIC”) as co-crosslinker and trimethylolpropane trimethacrylate (“TMPTMA”) and, as further additives, preferably a polyolefin ionomer and a polysiloxane for hydrophobization. This film has a reduced PID effect. However, a disadvantage thereof is that polyolefin ionomers are relatively costly. Moreover, polysiloxanes have an adverse effect on adhesion properties. In addition, the examples do not give any specific information as to what improvements are achievable with what concentrations.

A crosslinker combination of TAIC and TMPTMA is also described by JP 2007-281135 A. The TMPTMA here brings about acceleration of the crosslinking reaction and hence leads to elevated productivity.

JP 2012-067174 A and JP 2012-087260 A respectively describe an EVA-based and a polyolefin-based encapsulation film for solar cells, comprising, as well as TAIC, for example, ethylene glycol dimethacrylate, neopentyl glycol dimethacrylate, hexane-1,6-diol dimethacrylate as crosslinker. These co-crosslinkers slow the crosslinking reaction at the start somewhat and as a result increase the processing time window.

JP 2009-135200 A likewise describes crosslinkers comprising TAIC and various (meth)acrylate derivatives of polyfunctional alcohols, and what is described in this case is improved heat resistance combined with a lower tendency to delamination of the EVA-based encapsulation.

JP 2007-281135 A and JP 2007-305634 A describe crosslinker combinations of TAIC and trimethylolpropane triacrylate (“TMPTA”) for use in the production of multilayer co-extruded EVA encapsulation films for solar cells.

Similar combinations of crosslinkers for solar cell encapsulation films are described, for example, by JP 2013-138094 A, JPH11-20094, JPH11-20095, JPH11-20096, JPH11-20097, JPH11-20098, JPH11-21541, CN 102391568 A, CN 102504715 A, CN 102863918 A, CN 102911612 A, CN 103045105 A, CN 103755876 A, CN 103804774 A, US 2011/0160383 A1, WO 2014/129573 A1.

A further group of crosslinkers in another context (treatment of printing platens) is described in the related art (EP 0 228 638 A1, DE 37 04 067 A1). These are crosslinkers of the chemical structure (II) defined below, especially methylenebisacrylamide.

However, this compound class, if it is to be used in the use for production of encapsulation films for solar cells described in the related art, brings disadvantages that make it unattractive for this purpose.

This is because polyolefin copolymer film is conventionally produced (explained hereinafter with reference to the EVA film, but also applicable to other polyolefin copolymer films) by initially charging EVA and spraying the crosslinker or a mixture of the particular crosslinker with further additives such as peroxides or co-crosslinkers onto the EVA. The solution sprayed on can then be allowed to diffuse in, and then the film can be extruded. However, this process is a non-starter in the case of crosslinkers of the chemical structure (II) defined below, especially methylenebisacrylamide, since they are not liquid.

It is true that, according to the related art, in the case of non-liquid crosslinkers, there is the option of dissolving them in a suitable solvent and only then of spraying them onto the EVA together with any further additives. However, this course of action brings disadvantages, since the solvent has to be removed again before or during the extrusion, which means additional complexity and capital costs and leads to high costs specifically in the case of industrial scale applications. Moreover, many of the possible solvents, for example methanol, are toxic and inflammable, which necessitates additional precautions with regard to occupational safety and explosion protection.

Direct application of the pulverulent crosslinker to the EVA pellets together with the liquid additives is not an option because of the lack of adhesion of the crosslinker on the pellets. It is true that the powder is at first distributed homogeneously on the surface of the polymer pellets by means of the liquid additives and sticks at first to the moist surface. However, as soon as the liquid additives have diffused completely into the polymer, the solids no longer adhere to the surface and are rubbed off again by the movement of the pellets, and so separation takes place and homogeneous distribution is impossible. The film obtained with such a mixture has excessive inhomogeneities, which leads to unacceptable variations in the VR value with regard to the encapsulation films for solar cells.

A further way of introducing the pulverulent crosslinker into the polymer formulation is the direct separate gravimetric metering of the powder into the extruder in the film production. However, the problem here is that only very small concentrations of the crosslinker, based on the polyolefin copolymer, are required, and so exact metering is technically difficult to achieve.

### SUMMARY OF THE INVENTION

It was accordingly an object of the present invention to provide a composition which enables use of the crosslinkers of the chemical structure (II) which follows, especially methylenebisacrylamide, in the production of a polyolefin copolymer film (especially EVA film), where the film thus obtained should have such a high VR value that it can be used for encapsulation of solar cells. In addition, a process for producing such films was to be provided.

It has now been found that, surprisingly, the problem addressed by the invention is solved by the dispersions defined hereinafter.

The present invention relates to a dispersion (D), comprising:

(i) at least one polyolefin copolymer (I) as continuous phase; and

(ii) at least one compound dispersed in the polyolefin copolymer (I) and having the chemical structure (II) with

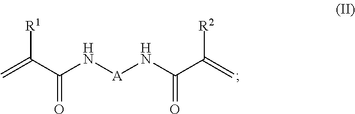

wherein

R¹, R² are each independently hydrogen or methyl;

A is selected from the group consisting of the following a, b and c)
a) an unbranched or branched alkylene group which has 1 to 20 carbon atoms and in which at least one hydrogen radical may be replaced by a halogen radical and in which one or two hydrogen radicals may each be replaced by a radical selected from the group consisting of —OR³, and —C(═O)NR⁴R⁵,
b) arylene group which has 6 to 14 carbon atoms and in which at least one hydrogen radical may be replaced by a halogen radical or an alkyl radical having 1 to 10 carbon atoms and in which one or two hydrogen radicals may each be replaced by a radical selected from the group consisting of —OR⁶, and —C(═O)NR⁷R⁸, and
c) a bridging radical of the chemical structure -A¹-X-A²-;
   wherein R³, R⁴, R⁵, R⁶, R⁷, R⁸ are each independently selected from the group consisting of hydrogen, and a branched or unbranched alkyl radical having 1 to 10 carbon atoms;
   wherein A¹, A² are each independently a branched or unbranched alkylene group having 1 to 10 carbon atoms;
   and wherein X is selected from the group consisting of —O—, —S—S—, —S—, and —NR⁹— with R⁹=alkyl radical having 1 to 10 carbon atoms.

In one embodiment, the present invention relates to a dispersion (D) as above, wherein R¹═R²=hydrogen and A=—CH₂—.

In one embodiment, the present invention relates to a film for encapsulation of an electronic device, comprising:

the above dispersion (D) in crosslinked form.

In another embodiment, the present invention relates to a method for encapsulating an electronic device, comprising:

contacting said electronic device with the above dispersion (D) and crosslinking said dispersion (D).

In a further embodiment, the present invention relates to a process for producing a film for encapsulation of an electronic device, comprising

(a) mixing the above dispersion (D) with additional polyolefin copolymer (I) to give a mixture;

(b) extruding the mixture obtained in step (a) to give a film.

In one embodiment, the present invention relates to a process for producing a dispersion (D), comprising:

(a) providing a polyolefin copolymer (I);

(b) adding at least one pulverulent compound of the chemical structure (II) to the polyolefin copolymer (I) with

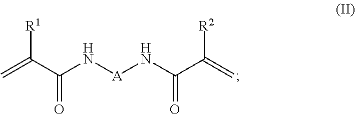

wherein

R¹, R² are each independently hydrogen or methyl;

A is selected from the group consisting of the following a, b and c)
a) an unbranched or branched alkylene group which has 1 to 20 carbon atoms and in which at least one hydrogen radical may be replaced by a halogen radical and in which one or two hydrogen radicals may each be replaced by a radical selected from the group consisting of —OR³, and —C(═O)NR⁴R⁵,
b) arylene group which has 6 to 14 carbon atoms and in which at least one hydrogen radical may be replaced by a halogen radical or an alkyl radical having 1 to 10 carbon atoms and in which one or two hydrogen radicals may each be replaced by a radical selected from the group consisting of —OR⁶, and —C(═O)NR⁷R⁸, and
c) a bridging radical of the chemical structure -A¹-X-A²-;
   wherein R³, R⁴, R⁵, R⁶, R⁷, R⁸ are each independently selected from the group consisting of hydrogen, and a branched or unbranched alkyl radical having 1 to 10 carbon atoms;
   wherein A¹, A² are each independently a branched or unbranched alkylene group having 1 to 10 carbon atoms;
and wherein X is selected from the group consisting of —O—, —S—S—, —S—, and —NR⁹— with R⁹=alkyl radical having 1 to 10 carbon atoms;

(c) incorporating the compound of the chemical structure (II) into the polyolefin copolymer (I).

In one embodiment, the present invention relates to a dispersion (D) obtained by the above process.

In another embodiment, the present invention relates to a film for encapsulation of an electronic device, comprising:

the dispersion (D) as obtained by the above method in crosslinked form.

In one embodiment, the present invention relates to a process for producing a film for encapsulation of an electronic device, comprising

(a) mixing the dispersion (D) as obtained by the above method with additional polyolefin copolymer (I) to give a mixture;

(b) extruding the mixture obtained in step (a) to give a film.

### DETAILED DESCRIPTION OF THE INVENTION

Any ranges mentioned herein below include all values and subvalues between the lowest and highest limit of this range.

The dispersions according to the present invention can surprisingly be used for production of films for encapsulation of electronic devices, for example solar cells, with a specific resistivity having a high value over the entire film.

The dispersion (D) according to the invention accordingly comprises

(i) at least one polyolefin copolymer (I) as continuous phase; and

(ii) at least one compound dispersed in the polyolefin copolymer (I) and having the chemical structure (II) with

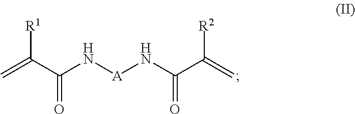

where

R¹, R² are each independently hydrogen or methyl;

A is selected from the group consisting of
unbranched or branched alkylene group which has 1 to 20 carbon atoms and in which at least one hydrogen radical may be replaced by a halogen radical and in which one or two hydrogen radicals may each be replaced by a radical selected from the group consisting of —OR³, —C(═O)NR⁴R⁵,
arylene group which has 6 to 14 carbon atoms and in which at least one hydrogen radical may be replaced by a halogen radical or an alkyl radical having 1 to 10 carbon atoms and in which one or two hydrogen radicals may each be replaced by a radical selected from the group consisting of —OR⁶, —C(═O)NR⁷R⁸,
a bridging radical of the chemical structure -A¹-X-A²-;
   where R³, R⁴, R⁵, R⁶, R⁷, R⁸ are each independently selected from the group consisting of hydrogen, branched or unbranched alkyl radical having 1 to 10 carbon atoms;
   where A¹, A² are each independently a branched or unbranched alkylene group having 1 to 10 carbon atoms;
   and where X is selected from the group consisting of —O—, —S—S—, —S—, —NR⁹— with R⁹=alkyl radical having 1 to 10 carbon atoms.

A compound of the chemical structure (II) is also referred to in the context of the invention as “(meth)acrylamide compound”.

More particularly, in the chemical structure (II),

R¹, R² are each independently hydrogen or methyl;

A is selected from the group consisting of
unbranched or branched alkyl group having 1 to 20 carbon atoms, arylene group having 6 to 14 carbon atoms, a bridging radical of the chemical structure -A′-X-A²-;
where A¹, A² are each independently a branched or unbranched alkylene group having 1 to 10 carbon atoms;
and where X is selected from the group consisting of —O—, —S—S—, —S—, —NR⁹— with R⁹=unbranched or branched alkyl radical having 1 to 10 carbon atoms.

In a preferred embodiment of the dispersion (D), in the chemical structure (II), R¹, R² are each independently hydrogen or methyl; A is selected from the group consisting of unbranched or branched alkylene group having 1 to 20 carbon atoms, arylene group having 6 to 14 carbon atoms, a bridging radical of the chemical structure -A¹-O-A²- where A¹, A² are each independently a branched or unbranched alkylene group having 1 to 10 carbon atoms.

In a more preferred embodiment of the dispersion (D), in the chemical structure (II), R¹, R² are each independently hydrogen or methyl, and are especially both hydrogen or both methyl; A selected from the group consisting of unbranched or branched alkylene group having 1 to 12 carbon atoms, phenylene, —(CH₂)₂—O—(CH₂)₂—, —CH₂—O—CH₂—.

In an even more preferred embodiment of the dispersion (D), in the chemical structure (II), R¹═R²=hydrogen or R¹═R²=methyl; A is selected from the group consisting of unbranched or branched alkylene group having 1 to 12, especially 1 to 10, preferably 1 to 8 and more preferably 1 to 6 carbon atoms, —(CH₂)₂—O—(CH₂)₂—, —CH₂—O—CH₂—. Such compounds of the chemical structure (II) are, for example, N,N′-methylenediacrylamide, N,N′-methylenedimethacrylamide, N,N′-ethylenediacrylamide, N,N′-hexamethylenediacrylamide, bisacrylamide dimethyl ether.

In an even more particularly preferred embodiment of the dispersion (D), in the chemical structure (II), R¹═R²=hydrogen; A is selected from the group consisting of unbranched or branched alkylene group having 1 to 12, especially 1 to 10, preferably 1 to 8 and more preferably 1 to 6 carbon atoms, —(CH₂)₂—O—(CH₂)₂—, —CH₂—O—CH₂—.

Such compounds of the chemical structure (II) are, for example, N,N′-methylenediacrylamide, N,N′-ethylenediacrylamide, N,N′-hexamethylenediacrylamide, bisacrylamide dimethyl ether.

N,N′-Methylenediacrylamide is a compound of the structure (II) with R¹═R²═H and A=—CH₂—.

N,N′-Methylenedimethacrylamide is a compound of the structure (II) with R¹═R²═CH₃ and A=—CH₂—.

N,N′-Ethylenediacrylamide is a compound of the structure (II) with R¹═R²═H and A=—CH₂—CH₂—.

N,N′-Hexamethylenediacrylamide is a compound of the structure (II) with R¹═R²═H and A=—(CH₂)₆—.

Bisacrylamide dimethyl ether is a compound of the structure (II) with R¹═R²═H and A=—CH₂—O—CH₂—.

An “alkylene group” in the context of the invention is a divalent saturated hydrocarbyl radical.

An “arylene group” in the context of the invention is a divalent aromatic hydrocarbyl radical, for example naphthalene, phenanthrene, phenylene.

“Phenylene” in the context of the invention encompasses 1,2-phenylene, 1,3-phenylene, 1,4-phenylene.

An unbranched or branched alkylene group having 1 to 6 carbon atoms is especially selected from methylene, ethylene, n-propylene, n-butylene, n-pentylene, n-hexylene. “n-Hexylene” is equivalent to “hexamethylene”.

“Dispersion”, according to art knowledge and in the context of the invention, means a composition comprising insoluble solid particles (“insoluble solid particles” are also referred to hereinafter as “particles”) in a continuous phase which may be solid or liquid, but is preferably solid.

In the dispersion (D) according to the invention, the polyolefin copolymer (I) is the continuous phase, which may be solid or liquid, but is preferably solid, and the compound of the chemical structure (II) is the dispersed phase.

The dispersion (D) is especially suitable as a masterbatch in the solvent-free production of EVA films having constantly high specific resistivity and is therefore especially outstandingly suitable for industrial scale applications. It has been found that, completely surprisingly, it is possible with the dispersions (D) according to the invention to produce EVA films especially without use of additional solvents and especially to produce films having a higher minimal VR value than films which have been produced by conventional processes reliant on the use of solvents.

There is no particular restriction in the proportion of all compounds of the chemical structure (II) in the dispersion (D) based on the total weight of all polyolefin copolymers (I) encompassed by the dispersion (D). Preferably, however, the proportion of all compounds of the chemical structure (II) based on the total weight of all the polyolefin copolymers (I) encompassed by the dispersion (D) is in the range of 0.1% to 25.0% by weight, more preferably 1.0% to 11.1% by weight, even more preferably 2.0% to 10.0% by weight, even more preferably still 3.0% to 9.0% by weight, most preferably 5.3% to 8.1% by weight.

Polyolefin copolymers (I) usable in accordance with the invention are known to those skilled in the art and are described, for instance, in WO 2008/036708 A2 and JP 2012-087260.

More particularly, in accordance with the invention, polyolefin copolymers (I) used are ethylene/α-olefin interpolymers, the term “interpolymer” meaning that the polyolefin copolymer in question has been prepared from at least two different monomers. Thus, the term “interpolymer” especially includes polyolefin copolymers formed from exactly two monomer units, but also terpolymers (for example ethylene/propylene/1-octene, ethylene/propylene/butene, ethylene/butene/1-octene, ethylene/butene/styrene) and tetrapolymers.

Useful polyolefin copolymers in accordance with the invention are especially ethylene/α-olefin copolymers which preferably do not have any further monomer units aside from ethylene and the α-olefin, the “α-olefin” in the context of the invention preferably being selected from the group consisting of propene, 1-butene, 4-methyl-1-pentene, 1-hexene, 1-octene, 1-decene, 1-dodecene, 1-tetradecene, 1-hexadecene, 1-octadecene, 3-cyclohexyl-1-propene, vinylcyclohexane, acrylic acid, methacrylic acid, norbornene, styrene, methylstyrene, vinyl acetate.

Even more preferably, the polyolefin copolymer according to the invention in the dispersion (D) is an ethylene-vinyl acetate copolymer.

If polyolefin copolymers used are ethylene/α-olefin interpolymers, these especially have α-olefin content in the range of 15% to 50% by weight, based on the total weight of the ethylene/α-olefin interpolymer. Preferably, the α-olefin content is in the range of 20% to 45% by weight, more preferably in the range of 25% to 40% by weight, even more preferably 26% to 34% by weight, most preferably 28% to 33% by weight, based in each case on the total weight of the ethylene/α-olefin interpolymer.

In the preferred embodiment in which the polyolefin copolymer is an ethylene-vinyl acetate copolymer, the ethylene-vinyl acetate copolymer especially has a vinyl acetate content in the range of 15% to 50% by weight, based on the total weight of the ethylene-vinyl acetate copolymer. Preferably, the vinyl acetate content in that case is in the range of 20% to 45% by weight, more preferably in the range of 25% to 40% by weight, even more preferably 26% to 34% by weight, most preferably 28% to 33% by weight, based in each case on the total weight of the ethylene/vinyl acetate copolymer.

The α-olefin content, especially the content of vinyl acetate in the case of the ethylene/vinyl acetate copolymer, is determined here by the method described in ASTM D 5594: 1998 [“Determination of the Vinyl Acetate Content of Ethylene-Vinyl Acetate (EVA) Copolymers by Fourier Transform Infrared Spectroscopy”].

More particularly, in the dispersion (D), the compound of the chemical structure (II) is present in particles in the continuous phase formed by the polyolefin copolymer (I). In order to achieve a maximum VR value of the polymer film, it is advantageous when the compound of the chemical structure (II) is present in very fine distribution in the polyolefin copolymer (I). More particularly, therefore, the dispersed compound of the chemical structure (II) is present in particles, where at least 50% of all the particles of the chemical structure (II) encompassed by the dispersion (D) have a particle size of ≦100 μm, preferably of ≦75 μm, more preferably ≦50 μm. At the same time, especially at least 50% of all the particles of the chemical structure (II) encompassed by the dispersion (D) have a particle size in the range of 1 μm to 100 μm, preferably 1 μm to 75 μm, more preferably 1 μm to 50 μm. Most preferably, 95% of the particles have a particle size of ≦25 μm; in particular, 95% of the particles have a particle size in the range of 1 μm to 25 μm.

It is also advantageous when the particles do not exceed a certain maximum size in order to minimize possible inhomogeneities in the film produced with dispersion (D).

In a further, even more preferred embodiment of the dispersion (D), the dispersed compound of the chemical structure (II) is present in particles, where all the particles have a particle size of ≦1 mm.

According to the invention, “particle size” is defined as the diameter of the smallest possible sphere that can be drawn around the particular particle irrespective of its shape and at the same time completely encompasses the particle.

According to the invention, the particle size is determined with the aid of light microscopy. This is done by compressing polymer pellets of the mixture according to the invention to give a film having a thickness of not more than 0.5 mm and examining it with a light microscope (Zeiss Axioscope M2m).

The pellets are first heated to a temperature above the melting point of the polyolefin copolymer (in the case of EVA, for example, 120° C.). The subsequent compression of the hot polymer melt is effected gently, in such a way that the polymer flows at a low applied pressure of <500 g/cm² without damaging the particles. Thereafter, at first with a survey magnification (imaging with 10× lens and an image section of 1420 μm), eight images are examined with regard to particle size distribution. Small particles are detected with the detail magnification (imaging with 100× lens and an image section of 142 μm), with examination of eight images in this case too. Evaluation is effected with the Image Pro Plus image processing software (from Media Cybernetics), with which the image is automatically evaluated, i.e. the number and size of the particles are determined. In addition, with the aid of the software, it is possible to display the percentage of particles <100 μm. In order to ensure a representative conclusion as to the particle size distribution, the different film sections are evaluated and used to calculate a mean. All the images are taken in different regions of the sample in order to avoid multiple detection of individual particles.

The dispersion (D), in a further embodiment of the invention, is used to produce a film for encapsulation of an electronic device.

The present invention accordingly also encompasses a first process for producing a film for encapsulation of an electronic device, comprising

(a) mixing the dispersion (D) with further polyolefin copolymer (I) to give a mixture;

(b) extruding the mixture obtained in step (a) to give a film.

The further polyolefin copolymer added in step (a) of the first process according to the invention for producing a film for encapsulation of an electronic device may be the same as or different from the polyolefin copolymer encompassed by the dispersion (D) used in step (a) of the process according to the invention, but is preferably the same, and both are more preferably ethylene-vinyl acetate copolymer, even more preferably having the same vinyl acetate content.

There is no particular restriction in the amount of the polyolefin copolymer which is added in step (a) of the first process according to the invention for producing a film for encapsulation of an electronic device. More particularly, a sufficient amount of polyolefin copolymer is added that the ratio of polyolefin copolymer (I) to compound of the chemical structure (II) desired in the film extruded in step (b) is established. Preferably, when the proportion of all the compounds of the chemical structure (II) in the dispersion (D) used in step (a) of the process for producing a film for encapsulation of an electronic device, based on the total weight of all the polyolefin copolymers (I) encompassed by the dispersion (D), is in the range of 0.1% to 25.0% by weight, more preferably 1.0% to 11.1% by weight, even more preferably 2.0% to 10.0% by weight, even more preferably still 3.0% to 9.0% by weight, most preferably 5.3% to 8.1% by weight, a sufficient amount of further polyolefin copolymer (I) is added that the ratio of all compounds of the chemical structure (II) mixed in step (a) of the process according to the invention, based on the total weight of all the polyolefin copolymers (I) mixed in step (a) of the process according to the invention, is in the range from 0.01% to 8.0% by weight. It will be appreciated that, at the same time, the ratio of all the compounds of the chemical structure (II) mixed in step (a) of the process according to the invention, based on the total weight of all the polyolefin copolymers (I) mixed in step (a) of the process according to the invention, is lower than the proportion of all the compounds of the chemical structure (II) in the dispersion (D) used in step (a), based on the total weight of all the polyolefin copolymers (I) encompassed by the dispersion (D) used in step (a).

In a particular embodiment of the first process according to the invention for producing a film for encapsulation of an electronic device, further additives are added in step (a). According to the invention, these additives are selected from the group consisting of initiators, further crosslinkers, silane coupling agents, antioxidants, ageing stabilizers, metal oxides, metal hydroxides, white pigments. Even more preferably, the additives are selected from the group consisting of initiators (for example tert-butyl peroxy-2-ethylhexylcarbonate), further crosslinkers (for example triallyl isocyanurate), silane coupling agents (for example γ-methacryloyloxypropyltrimethoxysilane).

According to the invention, initiators are free-radical formers activatable by heat, light, moisture or electron beams.

The initiator is preferably selected from the group consisting of peroxidic compounds, azo compounds, photoinitiators. More preferably, the initiator is selected from the group consisting of peroxidic compounds, azo compounds. Examples of these are described in the “Encyclopedia of Chemical Technology 1992, 3rd Edition, Vol. 17, pages 27-90”.

Peroxidic compounds are especially organic peroxides, which are in turn selected from the group consisting of dialkyl peroxides, diperoxy ketals, peroxycarboxylic esters, peroxycarbonates.

Dialkyl peroxides are especially selected from the group consisting of dicumyl peroxide, di-tert-butyl peroxide, di-tert-hexyl peroxide, tert-butylcumyl peroxide, iso-propylcumyl tert-butyl peroxide, tert-hexylcumyl peroxide, 2,5-dimethyl-2,5-di(tert-butylperoxy)hexane, 2,5-dimethyl-2,5-di(tert-amylperoxy)hexane, 2,5-dimethyl-2,5-di(tert-butylperoxy)-hex-3-yne, 2,5-dimethyl-2,5-di(tert-amylperoxy)hex-3-yne, α,α-di[(tert-butylperoxy)-iso-propyl]benzene, di-tert-amyl peroxide, 1,3,5-tri[(tert-butylperoxy)isopropyl]benzene, 1,3-dimethyl-3-(tert-butylperoxy)butanol, 1,3-dimethyl-3-(tert-amylperoxy)butanol, iso-propylcumyl hydroperoxide.

Diperoxy ketals are especially selected from the group consisting of 1,1-di(tert-butylperoxy)-3,3,5-trimethylcyclohexane, 1,1-di(tert-amylperoxy)cyclohexane, 1,1-di(tert-butylperoxy)cyclohexane, n-butyl 4,4-di(tert-amylperoxy)valerate, ethyl 3,3-di(tert-butylperoxy)butyrate, 2,2-di(tert-butylperoxy)butane, 3,6,6,9,9-pentamethyl-3-ethoxycarbonylmethyl-1,2,4,5-tetraoxacyclononane, 2,2-di(tert-amylperoxy)propane, n-butyl 4,4-bis(tert-butylperoxy)valerate.

Peroxycarboxylic esters are especially selected from the group consisting of tert-amyl peroxyacetate, tert-butyl peroxy-3,5,5-trimethylhexanoate, tert-amyl peroxybenzoate, tert-butyl peroxyacetate, tert-butyl peroxybenzoate, OO-tert-butyl monoperoxysuccinate, OO-tert-amyl monoperoxysuccinate.

Peroxycarbonates are especially selected from the group consisting of tert-butyl peroxy-2-ethylhexylcarbonate, tert-butyl peroxy-iso-propylcarbonate, tert-amyl peroxy-2-ethylhexylcarbonate, tert-amyl peroxybenzoate. A preferred peroxycarbonate is tert-butyl peroxy-2-ethylhexylcarbonate (“TBPEHC”).

The azo compound is preferably selected from the group consisting of 2,2′-azobis(2-acetoxypropane), 1,1′-azodi(hexahydrobenzonitrile).

More preferably, the initiator is selected from the group consisting of 2,5-dimethyl-2,5-di(tert-butylperoxy)hexane, tert-butyl peroxy-2-ethylhexylcarbonate, tert-butyl peroxy-3,5,5-trimethylhexanoate, 1,1-di(tert-butylperoxy)-3,5,5-trimethylcyclohexane, tert-amyl peroxy-2-ethylhexylcarbonate; most preferred is the initiator tert-butyl peroxy-2-ethylhexylcarbonate (“TBPEHC”).

There is no particular restriction in the mass of the peroxidic compound or of the azo compound, preferably of the peroxidic compound, which is used, based on the mass of the polyolefin copolymer. The peroxidic compound or the azo compound, preferably the peroxidic compound, is especially used in an amount of 0.05% to 10% by weight, preferably 0.1% to 5% by weight, more preferably 0.5% to 2% by weight, based in each case on the mass of all the polyolefin copolymers (I) mixed in step (a) of the process according to the invention.

Photoinitiators are especially selected from the group consisting of benzophenone, benzanthrone, benzoin, benzoin alkyl ethers, 2,2-diethoxyacetophenone, 2,2-dimethoxy-2-phenylacetophenone, p-phenoxydichloroacetophenone, 2-hydroxycyclohexylphenone, 2-hydroxyisopropylphenone, 1-phenylpropanedione 2-(ethoxycarbonyl) oxime.

The photoinitiator is especially used in an amount of 0.05% to 10% by weight, preferably 0.1% to 5% by weight, more preferably 0.2% to 3% by weight, even more preferably 0.25% to 1% by weight, based in each case on the mass of all the polyolefin copolymers (I) mixed in step (a) of the process according to the invention.

The term “further crosslinker” in the context of the invention implies that this crosslinker is not a compound of the chemical structure (II).

Crosslinkers here are preferably selected from the group consisting of triallyl isocyanurate, triallyl cyanurate, trimethylolpropane triacrylate, trimethylolpropane trimethacrylate, divinylbenzene, acrylates and methacrylates of polyhydric alcohols. Acrylates and methacrylates of polyhydric alcohols are especially selected from the group consisting of ethylene glycol di(meth)acrylate, diethylene glycol di(meth)acrylate, polyethylene glycol di(meth)acrylate, neopentyl glycol di(meth)acrylate, hexane-1,6-diol di(meth)acrylate, nonane-1,9-diol di(meth)acrylate, decane-1,10-diol di(meth)acrylate. More preferably, the further crosslinker is triallyl isocyanurate.

There is no particular restriction here in the proportion of the crosslinkers used in step (a) of the process according to the invention. The crosslinker is especially used in an amount of 0.005% to 5% by weight, preferably 0.01% to 3% by weight, more preferably 0.05% to 3% by weight, even more preferably 0.1% to 1.5% by weight, based in each case on the mass of all the polyolefin copolymers (I) mixed in step (a) of the process according to the invention.

Silane coupling agents usable in accordance with the invention include all silanes having an unsaturated hydrocarbyl radical and a hydrolysable radical (described, for instance, in EP 2 436 701 B1, U.S. Pat. No. 5,266,627).

Unsaturated hydrocarbyl radicals are especially selected from the group consisting of vinyl, allyl, isopropenyl, butenyl, cyclohexenyl, γ-(meth)acryloyloxyallyl.

Hydrolysable radicals are especially selected from the group consisting of hydrocarbyloxy, hydrocarbonyloxy, hydrocarbylamino. Preferably, the hydrolysable radical is selected from the group consisting of methoxy, ethoxy, formyloxy, acetoxy, propionyloxy, alkylamino, arylamino.

Preferably, the silane coupling agent is selected from the group consisting of: vinyltriethoxysilane, vinyltris(β-methoxyethoxy)silane, vinyltriacetoxysilane, γ-acryloyloxypropyltrimethoxysilane, γ-methacryloyloxypropyltrimethoxysilane, N-(β-aminoethyl)-γ-aminopropyltrimethoxysilane, N-(β-aminoethyl)-γ-aminopropylmethyldimethoxysilane, γ-aminopropyltriethoxysilane, γ-glycidoxypropyltrimethoxysilane, γ-mercaptopropyltriethoxysilane, γ-chloropropyltrimethoxysilane, β-(3,4-ethoxycyclohexyl)ethyltrimethoxysilane, γ-mercaptopropyltrimethoxysilane. Particular preference is given to using, as a silane coupling agent, γ-methacryloyloxypropyltrimethoxysilane (abbreviated to “KBM”).

There is no particular restriction here in the proportion of the further crosslinker used in step (a) of the process according to the invention. The silane coupling agent is especially used in an amount of 0.05% to 5% by weight, preferably 0.1% to 2% by weight, based in each case on the mass of all the polyolefin copolymers (I) mixed in step (a) of the process according to the invention.

Antioxidants in the context of the invention are preferably selected from the group consisting of phenolic antioxidants, phosphorus antioxidants.

Phenolic antioxidants are especially selected from the group consisting of 4-methoxyphenol, 2,6-di-tert-butyl-4-methylphenol, tert-butylhydroquinone, stearyl β-(3,5-di-tert-butyl-4-hydroxyphenyl)propionate, pentaerythrityl tetrakis[3-(3,5-di-tert-butyl-4-hydroxyphenyl)propionate], hexadecyl 3,5-di-tert-butyl-4-hydroxybenzoate.

Phosphorus antioxidants are especially selected from the group consisting of triphenyl phosphite, tris(nonylphenyl) phosphite, distearylpentaerythritol diphosphite, tetra(tridecyl)-1,1,3-tris(2-methyl-5-tert-butyl-4-hydroxyphenyl)butane diphosphate, tetrakis(2,4-di-tert-butylphenyl)-4,4-biphenyl diphosphonite.

There is no particular restriction here in the proportion of antioxidants used in step (a) of the process according to the invention. The antioxidants are especially used in an amount of 0.01% to 0.5% by weight, preferably 0.05% to 0.3% by weight, based in each case on the mass of all the polyolefin copolymers (I) mixed in step (a) of the process according to the invention.

Ageing stabilizers in the context of the invention are especially selected from the group of the “hindered amine light stabilizers” (=“HALS”) and the UV absorbers.

HALS stabilizers in the context of the invention are especially compounds having at least one 2,2,6,6-tetramethyl-4-piperidyl radical, where the nitrogen atom at the 1 position of the piperidyl radical bears an H, an alkyl group or an alkoxy group.

Preference is given to HALS stabilizers selected from the group consisting of bis(2,2,6,6-tetramethyl-4-piperidyl) sebacate, 1,2,2,6,6-pentamethyl-4-piperidyl sebacate,

bis(1,2,2,6,6-pentamethyl-4-piperidyl) sebacate, bis(1-octyloxy-2,2,6,6-tetramethyl-4-piperidyl) sebacate, poly{(6-morpholino-S-triazine-2,4-diyl) [2,2,6,6-tetramethyl-4-piperidyl)imino]hexamethylene[(2,2,6,6-tetramethyl-4-piperidyl)imino]} having CAS Number 82451-48-7,

polymers of CAS Number 193098-40-7,

copolymer of dimethyl succinate and 1-(2-hydroxyethyl)-2,2,6,6-tetramethyl-4-piperidinol,

N,N′,N″,N″′,N″,N″′-tetrakis{4,6-bis[butyl(N-methyl-2,2,6,6-tetramethylpiperidin-4-yl)amino]triazin-2-yl}-4,7-diazadecane-1,10-diamine having CAS Number 106990-43-6.

There is no particular restriction here in the proportion of HALS stabilizers used in step (a) of the process according to the invention. The HALS stabilizers are especially used in an amount of 0.01% to 0.5% by weight, preferably 0.05% to 0.3% by weight, based in each case on the mass of all the polyolefin copolymers (I) mixed in step (a) of the process according to the invention.

UV absorbers are especially selected from the group consisting of 2-hydroxy-4-N-octoxybenzophenone, 2,4-di-tert-butylphenyl 3,5-di-tert-butyl-4-hydroxybenzoate, 2-hydroxy-4-methoxybenzophenone, 2,2-dihydroxy-4-methoxybenzophenone, 2-hydroxy-4-methoxy-4-carboxybenzophenone, 2-(2-hydroxy-3,5-di-tert-butylphenyl)benzotriazole, 2-(2-hydroxy-5-methylphenyl)benzotriazole, p-octylphenyl salicylate, 2-(4,6-diphenyl-1,3,5-triazin-2-yl)-5-[(hexyl)oxy]phenol, ethyl 2-cyano-3,3-diphenylacrylate.

There is no particular restriction here in the proportion of the UV absorbers encompassed by the dispersion (D). The proportion of all the UV absorbers encompassed by the dispersion (D) is especially 0.01% to 0.5% by weight, preferably 0.05% to 0.3% by weight, based in each case on the mass of all the polyolefin copolymers encompassed by the dispersion (D).

According to the invention, metal oxides are especially selected from the group consisting of alkali metal oxides, alkaline earth metal oxides, zinc oxide, preferably selected from the group consisting of magnesium oxide, zinc oxide.

There is no particular restriction here in the proportion of the metal oxides used in step (a) of the process according to the invention. The metal oxides are especially used in an amount of 0.01% to 10% by weight, preferably 0.05% to 3% by weight, based in each case on the mass of all the polyolefin copolymers (I) mixed in step (a) of the process according to the invention.

According to the invention, metal hydroxides are especially selected from the group consisting of alkali metal hydroxides, alkaline earth metal hydroxides, preferably selected from the group consisting of magnesium hydroxide, calcium hydroxide.

There is no particular restriction here in the proportion of the metal hydroxides used in step (a) of the process according to the invention. The metal hydroxides are especially used in an amount of 0.01% to 10% by weight, preferably 0.05% to 3% by weight, based in each case on the mass of all the polyolefin copolymers (I) mixed in step (a) of the process according to the invention.

White pigments in the context of the invention are especially selected from the group of titanium dioxide, zinc oxide, zinc sulphide, barium sulphate, lithopone.

There is no particular restriction here in the proportion of the white pigments used in step (a) of the process according to the invention. The white pigments are especially used in an amount of 5% to 25% by weight, preferably 10% to 20% by weight, even more preferably of 15% by weight, based in each case on the mass of all the polyolefin copolymers (I) mixed in step (a) of the process according to the invention.

The two steps of the first process according to the invention for producing a film for encapsulation of an electronic device may be performed by methods familiar to those skilled in the art.

Thus, in one embodiment, steps (a) and (b) can be conducted separately. This is especially accomplished by mixing the dispersion (D) in pellet form with further polyolefin copolymer (I), likewise in pellet form, and optionally further additives in a mixer [step (a)], followed by the metered addition of the mixture obtained in step (a) to an extruder in which this mixture is melted, mixed homogeneously and extruded to a film.

Alternatively and preferably, step (a) and (b) take place in one process step, wherein dispersion (D) in pellet form, together with further polyolefin copolymer (I), likewise in pellet form and optionally already comprising the additives, are metered simultaneously and independently into an extruder and mixed therein, and the mixture thus obtained is melted, homogenized and extruded to a film.

The dispersion (D) according to the invention is especially obtained by a process for producing the dispersion (D) comprising the following steps:

(a) providing a polyolefin copolymer (I);

(b) adding at least one pulverulent compound of the chemical structure (II) to the polyolefin copolymer (I) with

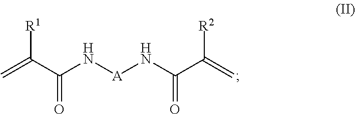

where

R¹, R² are each independently hydrogen or methyl;

A is selected from the group consisting of
unbranched or branched alkylene group which has 1 to 20 carbon atoms and in which at least one hydrogen radical may be replaced by a halogen radical and in which one or two hydrogen radicals may each be replaced by a radical selected from the group consisting of —OR³, —C(═O)NR⁴R⁵,
arylene group which has 6 to 14 carbon atoms and in which at least one hydrogen radical may be replaced by a halogen radical or an alkyl radical having 1 to 10 carbon atoms and in which one or two hydrogen radicals may each be replaced by a radical selected from the group consisting of —OR⁶, —C(═O)NR⁷R⁸,
a bridging radical of the chemical structure -A¹-X-A²-;
   where R³, R⁴, R⁵, R⁶, R⁷, R⁸ are each independently selected from the group consisting of hydrogen, branched or unbranched alkyl radical having 1 to 10 carbon atoms;
   where A¹, A² are each independently a branched or unbranched alkylene group having 1 to 10 carbon atoms;

and where X is selected from the group consisting of —O—, —S—S—, —S—, —NR⁹— with R⁹=alkyl radical having 1 to 10 carbon atoms;

(c) incorporating the compound of the chemical structure (II) into the polyolefin copolymer (I).

The incorporation in step (c) can be accomplished by methods known to those skilled in the art, for example in continuous mixing units, for example single-screw or twin-screw extruders or Buss co-kneaders or in batchwise kneaders or internal mixers. This ensures that the pulverulent compound of the chemical structure (II) is dispersed in the polyolefin copolymer.

In order to improve the incorporation of the pulverulent compound of the chemical structure (II) in step (c) of the process for producing the dispersion (D), the pulverulent compound of the chemical structure (II) used in step (b) especially has a particle size as follows: at least 50% of all particles encompassed by the pulverulent compound of the chemical structure (II) have a particle size of ≦500 μm, preferably of ≦400 μm, even more preferably ≦250 μm, most preferably ≦220 μm (also abbreviated to “d₅₀”). The particle size is determined in accordance with DIN/ISO 13320. Even more preferably, all the particles of the pulverulent compound of the chemical structure (II) used in step (b) have a particle size of ≦2 mm.

It should be noted that shear forces during the incorporation in step (c) of the process for producing the dispersion (D) reduce the particle size of the pulverulent compound of the chemical structure (II). The result is that the particle size of the particles of the dispersed compound of the chemical structure (II) on average is less than that of the particles of the pulverulent compound of the chemical structure (II) used.

The present invention also relates to a dispersion (D) obtainable by the process according to the invention for producing a dispersion (D), and to the use of this dispersion (D) for production of a film for encapsulation of an electronic device.

It is of course also possible to use the dispersion (D) obtained by the process according to the invention for producing a dispersion (D) in step (a) of the process according to the invention for producing a film for encapsulation of an electronic device.

The invention accordingly also encompasses a further, second process for producing a film for encapsulation of an electronic device, comprising

(a) mixing the dispersion (D) obtainable by the process according to the invention for producing a dispersion (D) with further polyolefin copolymer (I) to give a mixture;

(b) extruding the mixture obtained in step (a) to give a film.

Preferably, in step (a) of the second process for producing a film for encapsulation of an electronic device, further additives selected from the group consisting of initiators, further crosslinkers, silane coupling agents, antioxidants, ageing stabilizers, metal oxides, metal hydroxides, white pigments are added. These additives have the definitions and preferred embodiments described for the first process according to the invention for producing a film for encapsulation of an electronic device.

The two steps of the second process according to the invention for producing a film for encapsulation of an electronic device may be performed by methods familiar to those skilled in the art.

Thus, in one embodiment of the second process for producing a film for encapsulation of an electronic device, steps (a) and (b) can be conducted separately. This is especially accomplished by mixing the dispersion (D) obtainable by the process according to the invention for producing a dispersion (D) in pellet form with further polyolefin copolymer (I), likewise in pellet form, and optionally further additives in a mixer [step (a)], followed by the metered addition of the mixture obtained in step (a) to an extruder in which this mixture is melted, mixed homogeneously and extruded to a film.

Alternatively and preferably, step (a) and (b) take place in one process step, wherein, more preferably, dispersion (D) obtainable by the process according to the invention for producing a dispersion (D) in pellet form, together with further polyolefin copolymer (I), likewise in pellet form and optionally already comprising the additives, are metered simultaneously and independently into an extruder and mixed therein, and the mixture thus obtained is melted, homogenized and extruded to a film.

The examples which follow are intended to further illustrate the present invention, without any intention that it be restricted to these examples.

Having generally described this invention, a further understanding can be obtained by reference to certain specific examples which are provided herein for purposes of illustration only, and are not intended to be limiting unless otherwise specified.

### EXAMPLES

### 1. Chemicals Used

N,N-Methylenediacrylamide (=“MDAA”) was sourced from Merck. The density is 1.235 g/cm³ (30° C.); the bulk density of the product was 200 kg/m³. The particle size distribution was: d₅₀=220 μm (instrument: Beckman Coulter LS particle size analyser).

The triallyl isocyanurate used hereinafter was “TAICROS®” from Evonik Industries AG.

The γ-methacryloyloxypropyltrimethoxysilane (=“KBM”) used hereinafter was “Dynasylan Memo®” from Evonik Industries AG.

The tert-butyl peroxy-2-ethylhexylcarbonate (=“TBPEHC”) used hereinafter was sourced from United Initiators.

The EVA used hereinafter was “EVATANE 28-40” ® from Arkema having a vinyl acetate content of 28.3% by weight.

### 2. Production of the Masterbatches

2.1. Production of the Masterbatch for Example 1

For production of the masterbatch having an MDAA concentration of 1.0%, 5.0 kg of EVA pellets were extruded with 50 g of MDAA in a ThermoHaake PTW 16/25D. The EVA pellets were metered in by volumetric metering with the Brabender DDS 20 metering unit; the MDAA was fed in by means of a gravimetric powder metering unit (Brabender MiniTwin). After exiting the nozzles, the masterbatch was cooled to 20° C. in a water bath and pelletized by means of a strand pelletizer.

2.2 Production of the Masterbatch for Examples 2 and 5

For production of the masterbatch having an MDAA concentration of 5.3%, 5.0 kg of EVA pellets were extruded with 265 g of MDAA in a ThermoHaake PTW 16/25D. The EVA pellets were metered in by volumetric metering with the Brabender DDS 20 metering unit; the MDAA was fed in by means of a gravimetric powder metering unit (Brabender MiniTwin). After exiting the nozzles, the masterbatch was cooled to 20° C. in a water bath and pelletized by means of a strand pelletizer.

2.3. Production of the Masterbatch for Examples 3 and 6

For production of the masterbatch having an MDAA concentration of 8.1%, 5.0 kg of EVA pellets were extruded with 405 g of MDAA in a ThermoHaake PTW 16/25D. The EVA pellets were metered in by volumetric metering with the Brabender DDS 20 metering unit; the MDAA was fed in by means of a gravimetric powder metering unit (Brabender MiniTwin). After exiting the nozzles, the masterbatch was cooled to 20° C. in a water bath and pelletized by means of a strand pelletizer.

2.4. Production of the Masterbatch for Example 4

For production of the masterbatch having an MDAA concentration of 25.0%, 5.0 kg of EVA pellets were extruded with 1.25 kg of MDAA in a ThermoHaake PTW 16/25D. The EVA pellets were metered in by volumetric metering with the Brabender DDS 20 metering unit; the MDAA was fed in by means of a gravimetric powder metering unit (Brabender MiniTwin). After exiting the nozzles, the masterbatch was cooled to 20° C. in a water bath and pelletized by means of a strand pelletizer.

### 3. Preparation of the EVA Pellets for EVA Film Production

### Comparative Examples

### Example C1

A mixture of 2.02 g (8.11 mmol) of TAIC, 0.50 g of KBM and 4.0 g of TBPEHC was distributed homogeneously over 493.5 g of EVA. The EVA additive mixture was subsequently mixed in a tumbling mixer for 2 to 4 h.

### Example C2

1.25 g (8.11 mmol) of MDAA were dissolved in a mixture of 0.50 g of KBM, 4.0 g of TBPEHC and 15 g of methanol. The mixture was distributed homogeneously over 494.25 g of EVA. The EVA additive mixture was subsequently mixed in a tumbling mixer for 2 to 4 h and then dried in a vacuum drying cabinet at 35° C. for one hour in order to remove the methanol.

### Example C3

0.25 g (1.62 mmol) of MDAA were dissolved in a mixture of 2.25 g (9.03 mmol) of TAIC, 0.50 g of KBM, 4.0 g of TBPEHC and 1.7 g of methanol. The mixture was distributed homogeneously over 493 g of EVA. The EVA additive mixture was subsequently mixed in a tumbling mixer for 2 to 4 h and then dried in a vacuum drying cabinet at 35° C. for one hour in order to remove the methanol.

### Example C4

0.5 g (3.24 mmol) of MDAA were dissolved in a mixture of 2.0 g (8.02 mmol) of TAIC, 0.50 g of KBM, 4.15 g of TBPEHC and 1.73 g of methanol. The mixture was distributed homogeneously over 493 g of EVA. The EVA additive mixture was subsequently mixed in a tumbling mixer for 2 to 4 h and then dried in a vacuum drying cabinet at 35° C. for one hour in order to remove the methanol.

### Inventive Examples 1-6

### Example 1

2.25 g of TAIC, 0.5 g of KBM and 4 g of TBPEHC were mixed and distributed homogeneously over a pellet mixture consisting of 25 g of the masterbatch produced as described in section 2.1 (abbreviated hereinafter as “MB”) and 468.25 g of EVA. The EVA/MB additive mixture obtained was subsequently mixed in a tumbling mixer for 2-4 h.

### Example 2

2.25 g of TAIC, 0.5 g of KBM and 4 g of TBPEHC were mixed and distributed homogeneously over a pellet mixture consisting of 5.0 g of the masterbatch produced as described in section 2.2 and 488.25 g of EVA. The EVA/MB additive mixture obtained was subsequently mixed in a tumbling mixer for 2-4 h.

### Example 3

2.25 g of TAIC, 0.5 g of KBM and 4 g of TBPEHC were mixed and distributed homogeneously over a pellet mixture consisting of 2.5 g of the masterbatch produced as described in section 2.3 and 490.70 g of EVA. The EVA/MB additive mixture obtained was subsequently mixed in a tumbling mixer for 2-4 h.

### Example 4

2.25 g of TAIC, 0.5 g of KBM and 4 g of TBPEHC were mixed and distributed homogeneously over a pellet mixture consisting of 1.25 g of the masterbatch produced as described in section 2.4 and 492.0 g of EVA. The EVA/MB additive mixture obtained was subsequently mixed in a tumbling mixer for 2-4 h.

### Example 5

2.0 g of TAIC, 0.5 g of KBM and 4 g of TBPEHC were mixed and distributed homogeneously over a pellet mixture consisting of 10.0 g of the masterbatch produced as described in section 2.2 and 483.53 g of EVA. The EVA/MB additive mixture obtained was subsequently mixed in a tumbling mixer for 2-4 h.

### Example 6

2.25 g of TAIC, 0.5 g of KBM and 4 g of TBPEHC were mixed and distributed homogeneously over a pellet mixture consisting of 6.67 g of the masterbatch produced as described in section 2.3 and 486.87 g of EVA. The EVA/MB additive mixture obtained was subsequently mixed in a tumbling mixer for 2-4 h.

### 4. Film Extrusion

To produce EVA films, the EVA pellets conditioned in the respective Comparative Examples C1-C4 or Inventive Examples 1-7 were metered directly into a Brabender single-screw extruder (19 mm). The EVA melt was extruded through a slot die (10 cm) having adjustable gap width, the film was cooled continuously in a roller system to 50° C. (1st roll), 20° second roll, and then rolled up. The extruder settings are listed below:

### Extrusion Parameters for EVA Film Production

Heating zone temperatures [° C.]

| | |
|---|---|
| T1 | 55 |
| T2 | 75 |
| T3 | 80 |
| T4 | 80 |
| Die | 82 |
| T(melt) | 84 |

### 5. Film Lamination

The lamination of the EVA film was conducted at 150° C. (machine setting) between Teflon release films, and the same temperature was kept constant over the entire lamination process. The duration of the one-stage devolatilization step was 100 s. Subsequently, the sample was subjected to a contact pressure of 0.7 kg/cm². The residence time in the laminator was 20 minutes.

### 6. Determination of Specific Resistivity ρ

For the determination of the resistivity of crosslinked EVA films of thickness 400 to 500 μm, samples having dimensions of about 8×8 cm were first stored at room temperature (22.5° C.) and a relative air humidity of 50% for up to 7 but at least for 4 days in order to assure a constant moisture level within the EVA film.

The resistivity measurement was conducted with a Keithley ohmmeter (6517B) and a corresponding test cell, likewise from Keithley (“resistivity test fixture 8009”). In accordance with ASTM D-257, the sample was subjected to a voltage of 500 V for 60 s and the current was measured after this time. The resistivity (VR) can then be calculated from the known parameters and is shown in Table 1 below.

TABLE 1

| | Ratio of | | | | | | |
|---|---|---|---|---|---|---|---|
| | MDAA/EVA | | | | | | |
| | in the | Amount | Amount of | Amount of | | | |
| Example | masterbatch | of MB | MDAA [g] | TAIC [g] | VR * 10¹⁵ | VRₘᵢₙ*10¹⁵ | VRₘₐₓ*10¹⁵ |
| No. | [% by wt.] | [g] | (mmol) | (mmol) | [ohm*cm] | [ohm*cm] | [ohm*cm] |
| C1 | | | — | 2.02 (8.11) | 2.2 | 1.8 | 2.6 |
| C2 | | | 1.25 (8.11) | — | 39.5 | 18.9 | 64.4 |
| C3 | | | 0.25 (1.62) | 2.25 (9.03) | 18.3 | 13.0 | 22.6 |
| 1 | 1 | 25.0 | 0.25 (1.62) | 2.25 (9.03) | 15.8 | 14.4 | 18.1 |
| 2 | 5.3 | 5.0 | 0.25 (1.62) | 2.25 (9.03) | 19.2 | 13.6 | 29.1 |
| 3 | 8.1 | 2.5 | 0.25 (1.62) | 2.25 (9.03) | 9.4 | 6.0 | 13.8 |
| 4 | 25 | 1.25 | 0.25 (1.62) | 2.25 (9.03) | 8.3 | 4.1 | 12.9 |
| C4 | | | 0.50 (3.24) | 2.0 (8.02) | 22.2 | 17.5 | 26.1 |
| 5 | 5.3 | 10.0 | 0.50 (3.24) | 2.0 (8.02) | 61.7 | 52.3 | 82.9 |
| 6 | 8.1 | 6.67 | 0.50 (3.24) | 2.0 (8.02) | 42.4 | 36.7 | 51.0 |

It is apparent from the results in the table that
in the case of use of a masterbatch composed of polyolefin copolymer, shown using EVA, and a compound of the chemical structure (II), shown using MDAA, it is possible to produce a film without having to resort to the use of a solvent.
Particular compositions of MDAA relative to EVA enable production of EVA films having a VR which assures a sufficiently high VR over the entire film. This is clear from the “VRₘᵢₙ” values in Table 1, which are even higher for values of 1 to 8.1 than when the solvent is used.

Both results were completely surprising.

European patent application EP14199296 filed Dec. 19, 2015, is incorporated herein by reference.

Numerous modifications and variations on the present invention are possible in light of the above teachings. It is therefore to be understood that within the scope of the appended claims, the invention may be practiced otherwise than as specifically described herein.

1. A dispersion (D), comprising:
(i) at least one polyolefin copolymer (I) as continuous phase; and
(ii) at least one compound dispersed in the polyolefin copolymer (I) and having the chemical structure (II) with 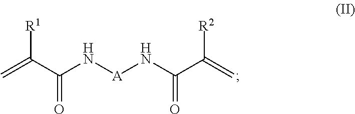
wherein
R¹, R² are each independently hydrogen or methyl;
A is selected from the group consisting of the following a, b and c)
a) an unbranched or branched alkylene group which has 1 to 20 carbon atoms and in which at least one hydrogen radical may be replaced by a halogen radical and in which one or two hydrogen radicals may each be replaced by a radical selected from the group consisting of —OR³, and —C(═O)NR⁴R⁵,
b) arylene group which has 6 to 14 carbon atoms and in which at least one hydrogen radical may be replaced by a halogen radical or an alkyl radical having 1 to 10 carbon atoms and in which one or two hydrogen radicals may each be replaced by a radical selected from the group consisting of —OR⁶, and —C(═O)NR⁷R⁸, and
c) a bridging radical of the chemical structure -A¹-X-A²-;
wherein R³, R⁴, R⁵, R⁶, R⁷, R⁸ are each independently selected from the group consisting of hydrogen, and a branched or unbranched alkyl radical having 1 to 10 carbon atoms;
wherein A¹, A² are each independently a branched or unbranched alkylene group having 1 to 10 carbon atoms;
and wherein X is selected from the group consisting of —O—, —S—S—, —S—, and —NR⁹— with R⁹=alkyl radical having 1 to 10 carbon atoms.

2. The dispersion (D) according to claim 1, wherein R¹═R²=hydrogen and A=—CH₂—.

3. The dispersion (D) according to claim 1, in which the proportion of all compounds of the chemical structure (II) based on a total weight of all polyolefin copolymers (I) in the dispersion (D) is in the range from 0.1% to 25% by weight.

4. The dispersion (D) according to claim 1, wherein the polyolefin copolymer (I) is an ethylene-vinyl acetate copolymer.

5. The dispersion (D) according to claim 1, wherein the polyolefin copolymer (I) is in the solid state of matter.

6. The dispersion (D) according to claim 5, in which the dispersed compound of the chemical structure (II) is present in particles, wherein at least 50% of all the particles of the chemical structure (II) in the dispersion (D) have a particle size of ≦100 μm.

7. The dispersion (D) according to claim 6, in which the dispersed compound of the chemical structure (II) is present in particles, wherein all the particles have a particle size of <1 mm.

8. A film for encapsulation of an electronic device, comprising:
the dispersion (D) according to claim 1 in crosslinked form.

9. The film according to claim 8, wherein the device is a solar cell.

10. A method for encapsulating an electronic device, comprising:
contacting said electronic device with the dispersion (D) of claim 1 and crosslinking said dispersion (D).

11. The method according to claim 10, wherein the device is a solar cell.

12. The method according to claim 11, wherein the crosslinking of the dispersion (D) occurs in the course of solar module lamination.

13. A process for producing a film for encapsulation of an electronic device, comprising
(a) mixing the dispersion (D) according to claim 1 with additional polyolefin copolymer (I) to give a mixture;
(b) extruding the mixture obtained in step (a) to give a film.

14. The process according to claim 9, wherein additives selected from the group consisting of initiators, further crosslinkers, silane coupling agents, antioxidants, ageing stabilizers, metal oxides, metal hydroxides, and white pigments are added in step (a).

15. A process for producing a dispersion (D), comprising:
(a) providing a polyolefin copolymer (I);
(b) adding at least one pulverulent compound of the chemical structure (II) to the polyolefin copolymer (I) with 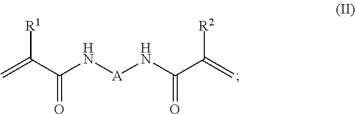
wherein
R¹, R² are each independently hydrogen or methyl;
A is selected from the group consisting of the following a, b and c)
a) an unbranched or branched alkylene group which has 1 to 20 carbon atoms and in which at least one hydrogen radical may be replaced by a halogen radical and in which one or two hydrogen radicals may each be replaced by a radical selected from the group consisting of —OR³, and —C(═O)NR⁴R⁵,
b) arylene group which has 6 to 14 carbon atoms and in which at least one hydrogen radical may be replaced by a halogen radical or an alkyl radical having 1 to 10 carbon atoms and in which one or two hydrogen radicals may each be replaced by a radical selected from the group consisting of —OR⁶, and —C(═O)NR⁷R⁸, and
c) a bridging radical of the chemical structure -A¹-X-A²-;
wherein R³, R⁴, R⁵, R⁶, R⁷, R⁸ are each independently selected from the group consisting of hydrogen, and a branched or unbranched alkyl radical having 1 to 10 carbon atoms;
wherein A¹, A² are each independently a branched or unbranched alkylene group having 1 to 10 carbon atoms;
and wherein X is selected from the group consisting of —O—, —S—S—, —S—, and —NR⁹— with R⁹=alkyl radical having 1 to 10 carbon atoms;
(c) incorporating the compound of the chemical structure (II) into the polyolefin copolymer (I).

16. The process according to claim 15, wherein R¹═R²=hydrogen and A=—CH₂—.

17. The process according to claim 15, wherein the polyolefin copolymer (I) is an ethylene-vinyl acetate copolymer.

18. The process according to claim 15, wherein at least 50% of all the particles encompassed by the pulverulent compound of the chemical structure (II) have a particle size of ≦500 μm, determined according to DIN/ISO 13320.

19. A dispersion (D) obtained by the process according to claim 15.

20. A film for encapsulation of an electronic device, comprising:
the dispersion (D) according to claim 19 in crosslinked form.

21. The film according to claim 20, wherein the device is a solar cell.

22. A process for producing a film for encapsulation of an electronic device, comprising
(a) mixing the dispersion (D) according to claim 19 with additional polyolefin copolymer (I) to give a mixture;
(b) extruding the mixture obtained in step (a) to give a film.

23. The process according to claim 22, wherein additives selected from the group consisting of initiators, further crosslinkers, silane coupling agents, antioxidants, ageing stabilizers, metal oxides, metal hydroxides, and white pigments are added in step (a).
